(19) United States
(12) Patent Application Publication
(10) Pub. No.: US 2007/0208968 A1
(43) Pub. Date: Sep. 6, 2007

(54) At-speed multi-port memory array test method and apparatus

(76) Inventors: Anand Krishnamurthy, Morrisville, NC (US); Clint Wayne Mumford, Apex, NC (US); Lakshmikant Mamileti, Cary, NC (US); Sanjay B Patel, Cary, NC (US)

Correspondence Address: QUALCOMM INCORPORATED, 5775 MOREHOUSE DR., SAN DIEGO, CA, 92121, US

(21) Appl. No.: 11/365,648

(22) Filed: Mar. 1, 2006

(51) Int. Cl. G11C 29/00

(52) U.S. Cl. 714/718

(57) ABSTRACT

A multi-port memory array is tested by simultaneously writing data to the array via two or more write ports, and/or simultaneously reading data from the array via two or more read ports, at the processor operating frequency. Comparing the data read from the array to that written to the array may be performed sequentially or in parallel. Comparator circuits are effectively disabled during normal processor operations. By simultaneously writing and/or reading data via multiple ports, latent electrical marginalities may be exposed. In addition, writing test patterns using multiple write ports and reading the patterns using multiple read ports significantly reduces test time during semiconductor manufacturing tests.

### FIELD

The present disclosure relates generally to the field of processors and in particular to a method testing multi-port memory arrays at operating frequency.

### BACKGROUND

Microprocessors perform computational operations in a wide variety of applications. A processor may serves as a central or main processing unit in a stationary computing system such as a server or desktop computer. High execution speed is a primary consideration for such desktop processors. In addition, processors are increasingly deployed in mobile computers such as laptops and Personal Digital Assistants (PDAs), and in embedded applications such as mobile phones, Global Positioning System (GPS) receivers, portable email clients, and the like. In such mobile applications, in addition to high execution speed, low power consumption and small size are desirable.

Many programs are written as if the computer executing them had a very large (ideally unlimited) amount of fast memory. Commonly modern processors simulate the ideal condition of unlimited fast memory by employing a hierarchy of memory types, each having different speed and cost characteristics. The memory types in the hierarchy vary from very fast and very expensive at the top, to progressively slower but more economical storage types in lower levels. A common processor memory hierarchy may comprise registers (gates) in the processor at the top level; backed by one or more on-chip caches comprised of Static Random Access Memory (SRAM); possibly an off-chip cache (SRAM); main memory Dynamic Random Access Memory (DRAM); disk storage (magnetic media with electromechanical access); and tape or Compact Disc (CD) (magnetic or optical media) at the lowest level. Most portable electronic devices have limited, if any, disk storage, and hence main memory, often limited in size, is the lowest level in the memory hierarchy.

High-speed, on-chip registers comprise the top level of a processor memory hierarchy. Discrete registers and/or latches are used as storage elements in the instruction execution pipeline. Most RISC instruction set architectures include a set of General Purpose Registers (GPRs) for use by the processor to store a wide variety of data, such as instruction op codes, addresses, offsets, operands for and the intermediate and final results of arithmetic and logical operations, and the like.

In some processors, the logical GPRs correspond to physical storage elements. In other processors, performance is improved by dynamically assigning each logical GPR identifier to one of a large set of storage locations, or physical registers (commonly known in the art as register renaming). In either case, the storage elements accessed by logical GPR identifiers may be implemented not as discrete registers, but rather as storage locations within a memory array. The registers or memory array storage elements implementing logical GPRs are multi-ported. That is, they may be written to, and/or their contents read by, several different processor elements, such as various pipeline stages, ALUs, cache memory, or the like.

Testing is an important part of IC manufacture, to identify and weed out defective or substandard components. Testing memory arrays is particularly problematic. Automatic Test Pattern Generation (ATPG) methodology comprises scanning an excitation pattern into one set of scan-chained registers or latches, applying the pattern to exercise random logic, capturing the results in another set of scan-chained registers or latches, and scanning the captured results out for comparison to expected values. Memory arrays cannot be efficiently tested using ATPG techniques due to the intermediate storage of test patterns in the array.

Memory arrays in a processor may be tested by functional testing, wherein code is executed in the processor pipeline to write test patterns to the array (e.g., to logical GPRs), then read the values and compare to expected values. Functional testing is time consuming and inefficient because the processor must be initialized and test code loaded into the cache prior to executing the tests. Additionally, the control and observation point—within the pipeline—is far removed from the memory locations being tested, and it may be difficult to isolate uncovered faults from intervening circuits.

Accordingly, many prior art processors with embedded memory arrays include a Built-In Self-Test (BIST) circuit that exercises the memory array during a test mode. A BIST controller writes data patterns to the memory array, reads the data patterns, and compares the read data to expected data. In functional mode, the BIST controller is inactive and the memory array is controlled by the processor control circuits. Prior art BIST systems include a dedicated test port in the memory array to write and/or read the array during testing. This places a lower boundary on the test duration by restricting memory access bandwidth; fails to test the memory I/O circuits, including the functional read and write ports; and may fail to uncover electrical marginalities that are only exposed when two or more ports access the array simultaneously.

### SUMMARY

According to one or more embodiments, a multi-port memory array is tested by a BIST controller by simultaneously writing data to the array via two or more write ports, and/or simultaneously reading data from the array via two or more read ports, at the processor operating frequency. Comparing the data read from the array to that written to the array may be performed sequentially or in parallel. Comparator circuits are effectively disabled during normal processor operations. By simultaneously writing and/or reading data via multiple ports, latent electrical marginalities may be exposed, and test time is reduced, as compared to prior art test methodologies.

One embodiment relates to a method of testing a memory array, having a plurality of write ports, in a processor. A first data pattern is writing to a first address in the array via a first write port. A second data pattern is simultaneously written to a second address in the array via a second write port. The first and second data patterns are read from the array. The first and second data patterns read from the array are compared to the first and second data patterns written to the array, respectively.

Another embodiment relates to a method of testing a memory array, having a plurality of read ports, in a processor. A first data pattern is written to a first address in the array. A second data pattern is written to a second address in the array. The first data pattern is read from the array via a first read port. The second data pattern is simultaneously read from the array via a second read port. The first and second data patterns read from the array are compared to the first and second data patterns written to the array, respectively.

Yet another embodiment relates to a method of testing a memory array in a processor. One or more predetermined data patterns are written to the array. The data patterns are simultaneously read from the array via two or more read ports, thereby exposing electrical marginalities in the array and/or the read ports not exposed by reading data via one read port at a time.

Still another embodiment relates to a processor. The processor includes a memory array having at least one write port and a plurality of latching read ports; a first data comparator having read data and compare data inputs, and outputting an indication whether the read data match the compare data pattern; and a first selector selectively directing data from two or more first read ports to the first comparator read data input. The processor additionally includes a BIST controller controlling the write port, first read ports, and first selector, providing write data to the write port and compare data to the first comparator compare data input, and receiving the first comparator output. The BIST controller operative to write one or more predetermined data patterns to the array via the write port; simultaneously read the written data from the array via two or more first read ports; and sequentially control the first selector to direct data from each first read port to the first comparator, provide corresponding compare data to the first comparator, and verify the array by inspecting the first comparator output.

### BRIEF DESCRIPTION OF DRAWINGS

FIG. 1 is a functional block diagram of a processor.

FIG. 2 is a functional block diagram of a memory array implementing a multi-port register file, and a BIST circuit.

FIG. 3 is a flow diagram of a method of BIST for a memory array by simultaneously writing test patterns via two or more write ports.

FIG. 4 is a flow diagram of a method of BIST for a memory array by simultaneously reading test patterns via two or more read ports.

### DETAILED DESCRIPTION

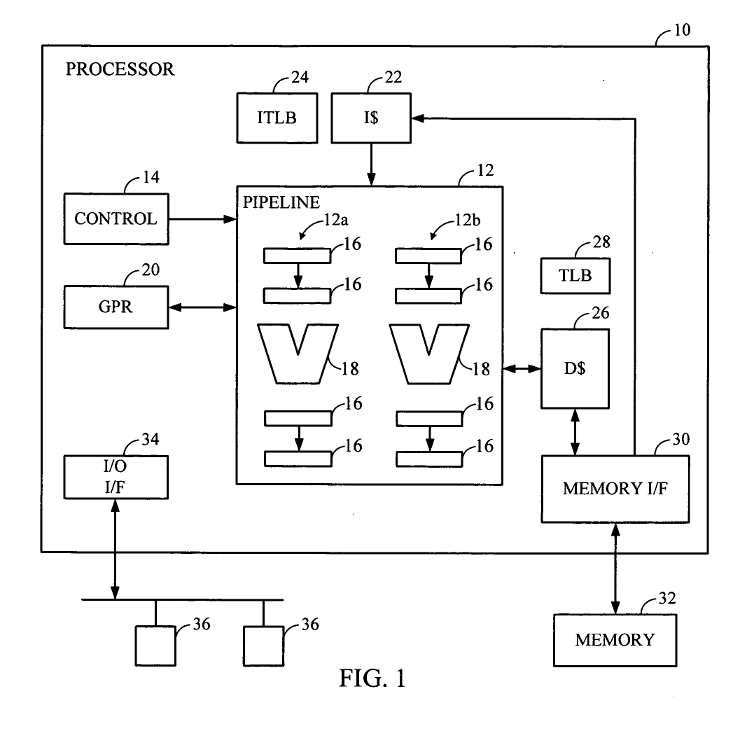

FIG. 1 depicts a functional block diagram of a processor 10. The processor 10 executes instructions in an instruction execution pipeline 12 according to control logic 14. The pipeline 12 may be a superscalar design, with multiple parallel pipelines such as 12a and 12b. The pipelines 12a, 12b include various registers or latches 16, organized in pipe stages, and one or more Arithmetic Logic Units (ALU) 18. A memory array 20 provides a plurality of storage locations that are mapped to logical General Purpose Registers (GPRs).

The pipelines 12a, 12b fetch instructions from an Instruction Cache (I-Cache) 22, with memory addressing and permissions managed by an Instruction-side Translation Lookaside Buffer (ITLB) 24. Data is accessed from a Data Cache (D-Cache) 26, with memory addressing and permissions managed by a main Translation Lookaside Buffer (TLB) 28. In various embodiments, the ITLB may comprise a copy of part of the TLB. Alternatively, the ITLB and TLB may be integrated. Similarly, in various embodiments of the processor 10, the I-cache 22 and D-cache 26 may be integrated, or unified. Misses in the I-cache 22 and/or the D-cache 26 cause an access to main (off-chip) memory 32, under the control of a memory interface 30. The processor 10 may include an Input/Output (I/O) interface 34, controlling access to various peripheral devices 36. Those of skill in the art will recognize that numerous variations of the processor 10 are possible. For example, the processor 10 may include a second-level (L2) cache for either or both the I and D caches. In addition, one or more of the functional blocks depicted in the processor 10 may be omitted from a particular embodiment.

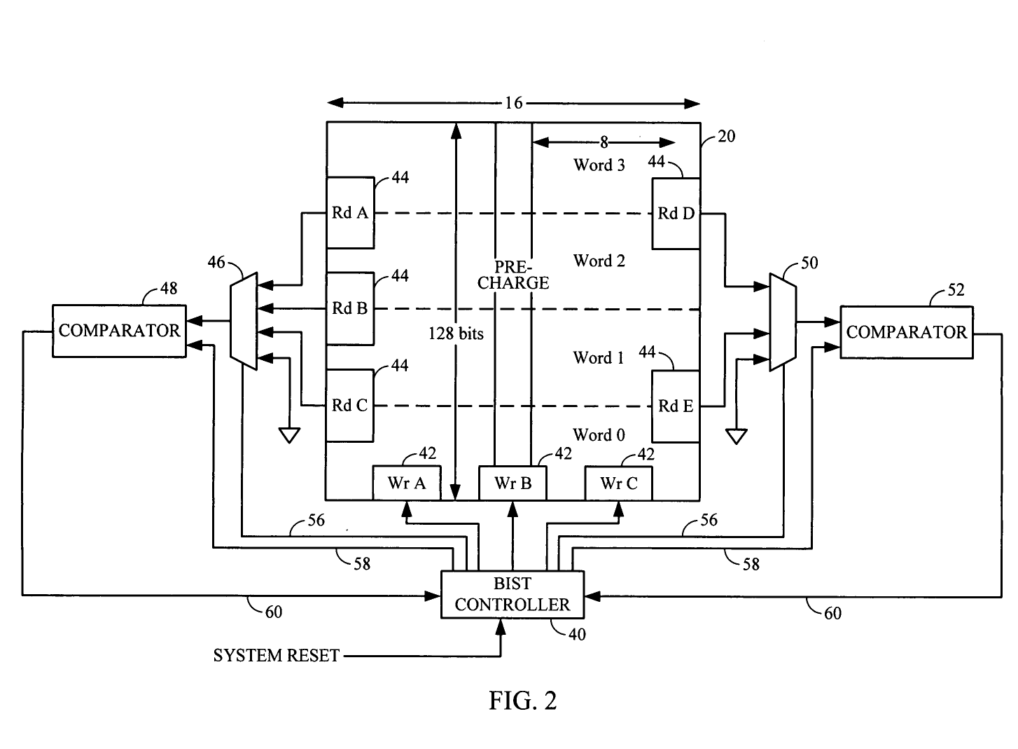

FIG. 2 depicts a multi-ported memory array 20 implementing a set of logical GPRs and Built-In Self Test (BIST) controller 40. The memory array 20 is organized as 128 bits by 16, although the test methodology and apparatus disclosed herein is applicable to any configuration of multi-ported memory. Each 128-bit location in the memory array 20 is a word-readable, and the array 20 is logically and physically segmented at word (32 bits) boundaries. A shared precharge and power distribution circuit is placed down the center of the memory array 20.

The particular memory array 20 depicted in FIG. 2 includes a three write ports 42 and five read ports 44, with three read ports 44 disposed along one side of the memory array 20, and to read ports 44 disposed of on the other side. This configuration is representative only. The three read ports 44 labeled A, B, and C are connected to a selector circuit 46, such as a multiplexer. The BIST controller 20 controls of the selector 46 via a control signal 56 to direct data read from the memory array 20 by one of read ports 44A, B, or C to the data end of a comparator 48. The BIST controller additionally provides a data patterns to the compare input of the comparator 48, along signal line 58. Data read by read ports 44D and E is a similarly directed through selector 52 a second comparator 52, width of the BIST controller 40 controlling the selector 50 and providing compare data to the comparator 52. The outputs of the comparators 48, 52 are directed to the BIST controller 40 along signal lines 60.

In test mode, the BIST controller 40 writes a background data pattern to the memory array 20 via write ports 42A, B, and/or C. The BIST controller 40 then writes test data patterns to one or more memory array 20 storage locations via write ports 42 A, B, and/or C. In at least some tests, the BIST controller 40 writes test data patterns via all a three write ports 40 simultaneously, to expose electrical marginalities in the memory array 20 that may not be observable when writing data through only one write port 42 at a time.

The BIST controller 40 then reads the test data patterns from the memory array 20 simultaneously via at least two read ports 44. To maximally stress the memory array 20 and expose any latent electrical marginalities, and additionally to minimize the test time, the BIST controller 40 simultaneously reads data via all available read ports 44 (i.e., all five read ports 44 in the embodiment depicted in FIG. 2). The BIST controller 40 then sequentially directs data from each read port 44 to a comparator 48, 52, simultaneously supplying the comparator 48, 52 with the corresponding expected data pattern, and inspects the output of the comparator 48, 52 to verify that the proper data pattern was read from the memory array 20. Because of the BIST controller 40 resides on the processor 10 component, all testing is performed “at speed,” that is, at the processor 10 operating frequency.

In the embodiment depicted in FIG. 2, in one test, the BIST controller 40 maximally stresses the memory array 20 and minimizes test time by simultaneously reading test patterns via all five read ports 44. The data from read ports 44A and D are then simultaneously directed to their respective comparator 48, 52, the appropriate compare patterns supplied, and the comparator outputs are verified. In the following cycle, data from read ports 44B and E are simultaneously verified. Finally, the data from read port 44C is a verified in comparator 48. The simultaneous reading of data from the memory array 20 by all five read ports 44 stresses the memory array 20 to expose latent electrical marginalities. Utilizing to comparators 48, 52 to simultaneously verify read data from to read ports 44 minimizes the test time.

Those of skill in the art will readily recognize that the number of comparators 48, 52 may be increased to further reduce test time by performing data comparisons in parallel. The test time may be minimized by providing a comparator 48, 52 for each read port 44 (obviating the need for a selector 46, 50). However, this increases silicon area, and may introduce wiring congestion, for test circuits that are not active during normal processor operation. At the other extreme, a single comparator 48, 50 may be provided, with data from all read ports 44 directed thereto via a single selector 46, 50. This minimizes the test circuitry, but places a lower limit on test duration, as each word in the memory array 20 must be compared sequentially. However, even with one comparator 48, 52, the memory array 20 may be more thoroughly and realistically tested than is possible with prior art test techniques, by simultaneously reading data via two or more (and up to all available) read ports 44.

The test apparatus and methodology disclosed herein additionally allows for more detailed diagnostics then prior art test systems, many of which are limited to a minimal functionality test (i.e., a go/no-go decision). The BIST controller 40 may write minimize test time by simultaneously writing test data patterns to three different storage locations via the three write ports 42, and simultaneously read data from five different storage locations via the five read ports 44. Alternatively, the BIST controller 40 may stress individual storage locations (and associated I/O circuits) by writing data to and/or reading data from a single storage location utilizing all available respective ports.

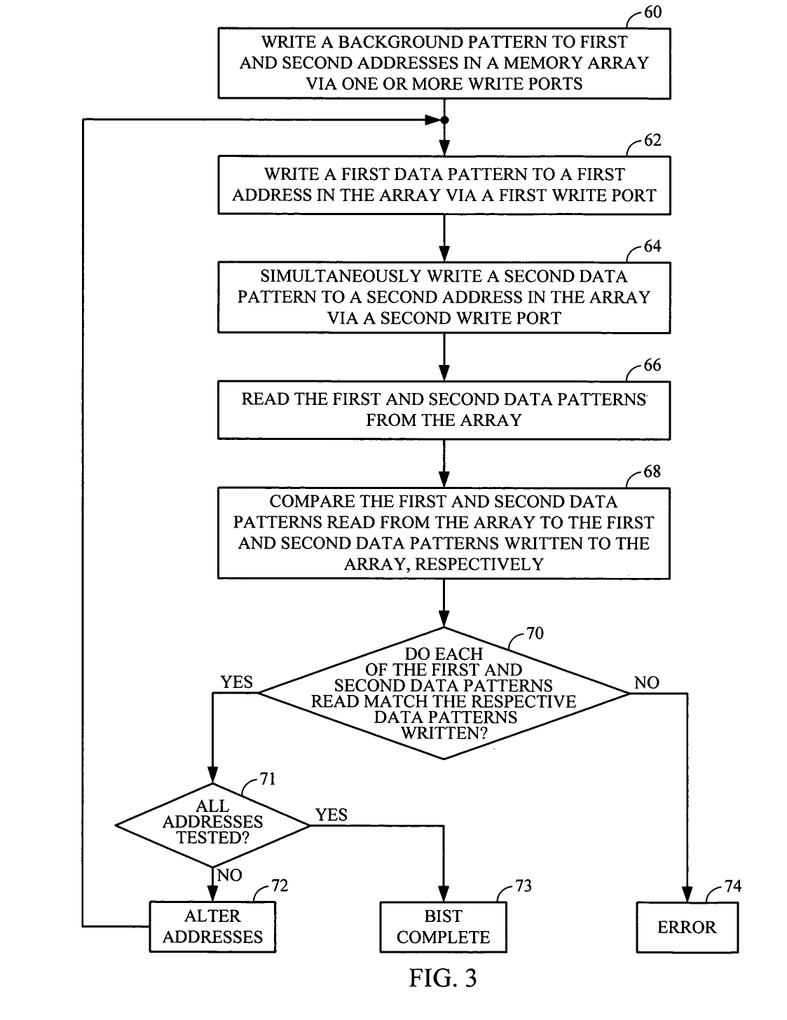

The test methodology is fully applicable to any memory array having two or more write ports 42 and/or two or more read ports 44. FIG. 3 depicts a method of BIST for a memory array having at least two write ports 42, regardless of the number of read ports 44 or comparators 48, 52. A background pattern is written to at least first and second addresses in the memory array 20 via one or more write ports (block 60). A first data pattern is written to a first address in the array 20 via a first write port 42 (block 62). Simultaneously, a second data pattern is written to a second address in the array 20 via a second write port 42 (block 64). The first and second data patterns may be the same, or they may be different. Similarly, the first and second addresses may be to adjacent memory location or be far apart. The first and second data patterns are read from the array 20 (block 66). If multiple read ports 44 are available, the data read operations may be performed simultaneously; alternatively, the read operations may be performed sequentially using a single read port 44. Each of the first and second data patterns read from the array 20 is compared to the respective data pattern written to the array 20 (block 68). If the data patterns match (block 70), and not all addresses have been tested (block 71), the addresses are altered (block 72), and testing proceeds. If the data patterns match (block 70), and all addresses have been tested (block 71), the BIST is complete (block 73). If the data patterns do not match (block 70), an error is flagged (block 74), which may indicate further testing, or that the memory array 20 and/or the relevant write port 42 and/or the read port(s) 44 is defective.

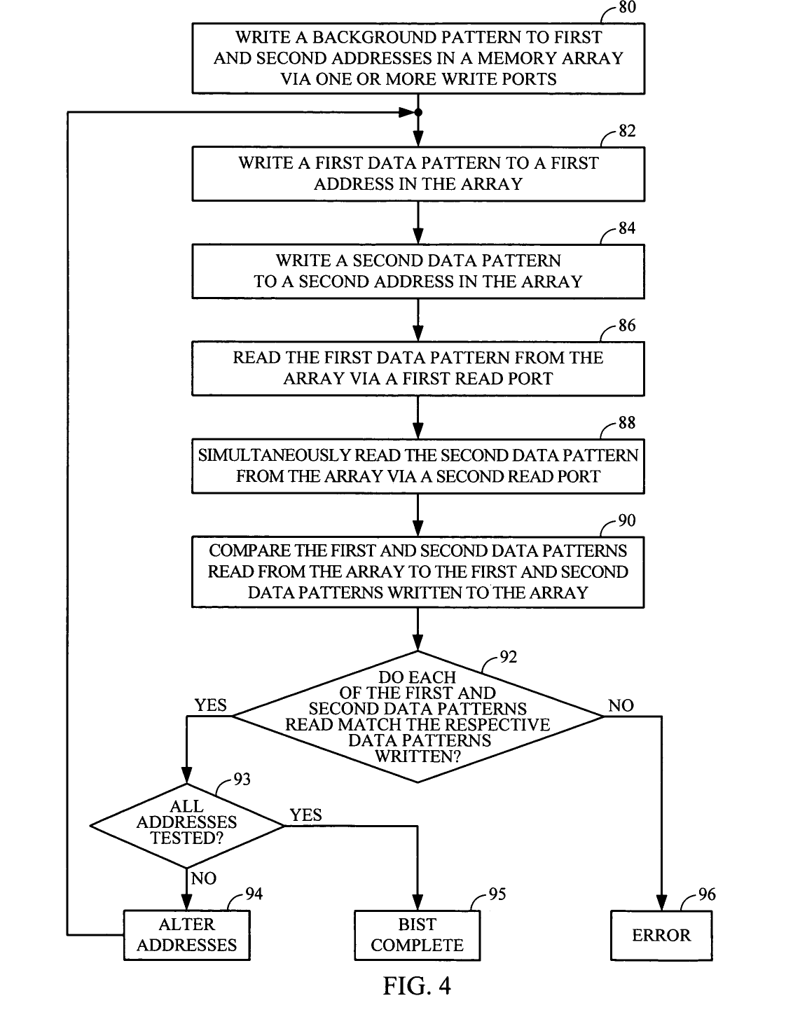

FIG. 4 depicts a method of BIST for a memory array having at least two read ports 44, regardless of the number of write ports 42 or comparators 48, 52. A background pattern is preferably written to at least first and second addresses in the memory array 20 (block 80). A first data pattern is written to a first address in the array 20 (block 82), and a second data pattern is written to a second address in the array 20 (block 84). If multiple write ports 42 are available, the first and second data patterns may be written simultaneously; otherwise, they may be written sequentially via a single write port 42. The first and second data patterns may be the same or different, and the first and second addresses may be adjacent or far apart. The first data pattern is read from the array 20 via a first read port 44 (block 86). Simultaneously, the second data pattern is read from the array 20 via a second read port 44 (block 88). Each of the first and second data patterns read from the array 20 is compared to the respective data pattern written to the array 20 (block 90). If more than one comparator is provided, the comparisons may be performed in parallel; alternatively they may be preformed sequentially. If the data patterns match (block 92), and not all addresses have been tested (block 93), the addresses are altered (block 94), and testing proceeds. If the data patterns match (block 92), and all addresses have been tested (block 93), the BIST is complete (block 95). If the data patterns to not match (block 92), an error is flagged (block 96).

Referring again to FIG. 2, the comparator circuits 48, 52 comprise a static logic gates. That is, the comparator 48, 52 will compare any data pattern presented at its data input to the data present at its compare input, and will generate a signal indicative of whether the data patterns match. During normal processor operation (i.e., not in test mode), the data output by the read ports 44 will constantly change. If at least one read port 44 is connected to the data input of a comparator 48, 52 by a selector 46, 50, logic gates within the comparator 48, 52 will be constantly switching, the consuming power, generating heat, and contributing to electrical noise on the power and ground rails.

Accordingly, the comparator circuits 48, 50 are effectively disabled during normal operations by ensuring that a constant data pattern is presented at the comparator 48, 52 data input. One input of each selector 46, 50 is tied to a constant data pattern, such as ground (as depicted in FIG. 2), although any data pattern may be utilized. Upon system reset (or in response to any other indicator that the processor is in normal operating mode), the BIST controller 40 directs the selector 46, 52 to select the fixed data pattern. This presents a static data pattern to the data input of the comparators 48, 52. The BIST controller 40 may optionally present a corresponding static data pattern to the compare input of the comparators 48, 52. Whether the comparator 48, 52 output indicates a data match or a miscompare, since the inputs are static, gates within the comparator 48, 52 will not switch beyond the initial one-cycle comparison.

Numerous latent electrical marginalities that may be exposed by simultaneously writing data patterns via two or more write ports 42, and/or by simultaneously reading data patterns via two or more read ports 44. Prior art test methods are completely unable to uncover these marginalities. When simultaneously writing data patterns via two or more write ports 42, multiple write drivers fire simultaneously. This stresses the power grid, which may expose marginalities. In addition, noise coupling between “quiet” and “switching” bit lines may be exposed.

Simultaneously reading data patterns via two or more read ports 44 may expose power grid marginalities by turning multiple prechargers “on” simultaneously. Similarly, multiple read bit lines are discharged simultaneously, which may also expose power grid marginalities. Power grid marginalities may further be exposed by multiple global and/or local word lines being turned “on” simultaneously. Noise coupling between “quiet” and “switching” bit lines may be exposed by multiple read bit lines being discharged simultaneously. In addition, multiple read data latch outputs switch simultaneously, causing coupling on long unshielded nets. This noise causes a delay pushout, which may expose noise and/or timing marginalities.

Although the present disclosure has been described herein with respect to particular features, aspects and embodiments thereof, it will be apparent that numerous variations, modifications, and other embodiments are possible within the broad scope of the present disclosure, and accordingly, all variations, modifications and embodiments are to be regarded as being within the scope of the disclosure. The present embodiments are therefore to be construed in all aspects as illustrative and not restrictive and all changes coming within the meaning and equivalency range of the appended claims are intended to be embraced therein.

What is claimed is:

1. A method of testing a memory array, having a plurality of write ports, in a processor, comprising:
writing a first data pattern to a first address in the array via a first write port;
simultaneously writing a second data pattern to a second address in the array via a second write port;
reading the first and second data patterns from the array; and
comparing the first and second data patterns read from the array to the first and second data patterns written to the array, respectively.

2. The method of claim 1, further comprising writing a background data pattern to at least the first and second addresses in the array, prior to writing the first and second data patterns.

3. The method of claim 1 wherein the first and second data patterns are the same.

4. The method of claim 1 wherein the first and second data patterns are different.

5. The method of claim 1 wherein the first and second addresses are adjacent.

6. The method of claim 1 wherein the first and second addresses are non-adjacent.

7. The method of claim 1 wherein the writing and reading of test patterns is performed at the integrated circuit operating frequency.

8. A method of testing a memory array, having a plurality of read ports, in an processor, comprising:
writing a first data pattern to a first address in the array;
writing a second data pattern to a second address in the array;
reading the first data pattern from the array via a first read port;
simultaneously reading the second data pattern from the array via a second read port; and
comparing the first and second data patterns read from the array to the first and second data patterns written to the array, respectively.

9. The method of claim 8, further comprising writing a background data pattern to at least the first and second addresses in the array, prior to writing the first and second data patterns.

10. The method of claim 8 wherein the first and second data patterns are the same.

11. The method of claim 8 wherein the first and second data patterns are different.

12. The method of claim 8 wherein the first and second addresses are the same.

13. The method of claim 8 wherein the first and second addresses are different.

14. The method of claim 8 wherein the writing and reading of test patterns is performed at the processor operating frequency.

15. The method of claim 8 wherein comparing the first and second data patterns read from the array to the first and second data patterns written to the array comprises simultaneously comparing the first and second data patterns read from the array to the first and second data patterns written to the array.

16. The method of claim 8 further comprising:
writing a third data pattern to a third address in the array;
reading the third data pattern from the array via a third read port simultaneously with reading the first and second data patterns; and
comparing the third data pattern read from the array to the third data pattern written to the array.

17. The method of claim 16 wherein comparing the data patterns comprises:
simultaneously comparing the first and second data patterns read from the array to the first and second data patterns written to the array; and
subsequently comparing the third data pattern read from the array to the third data pattern written to the array.

18. A method of testing a memory array in a processor, comprising:
writing one or more predetermined data patterns to the array;
simultaneously reading the data patterns from the array via two or more read ports, thereby exposing electrical marginalities in the array and/or the read ports not exposed by reading data via one read port at a time;

19. The method of claim 18 wherein writing one or more predetermined data patterns to the array comprises simultaneously writing predetermined data patterns to the array via two or more write ports, thereby exposing electrical marginalities in the array and/or the write ports not exposed by writing data via one write port at a time.

20. The method of claim 18 wherein the array writes and reads are performed at the processor operating frequency.

21. A processor, comprising:
a memory array having at least one write port and a plurality of latching read ports;
a first data comparator having read data and compare data inputs, and outputting an indication whether the read data match the compare data pattern;
a first selector selectively directing data from two or more first read ports to the first comparator read data input; and
a Built-In Self-Test (BIST) controller that controls the write port, the first read ports, and the first selector, and provides write data to the write port and compare data to the first comparator compare data input, and receives the first comparator output, the BIST controller operative to:
write one or more predetermined data patterns to the array via the write port;
simultaneously read the written data from the array via two or more first read ports; and
sequentially control the first selector to direct data from each first read port to the first comparator, provide corresponding compare data to the first comparator, and verify the array by inspecting the first comparator output.

22. The processor of claim 21 wherein the BIST controller is operative to write data patterns to different addresses in the array, and simultaneously read the written data from the different addresses via two or more first read ports.

23. The processor of claim 21 wherein the BIST controller is operative to write a data pattern to one address in the array, and simultaneously read the written data from that address via two or more first read ports.

24. The processor of claim 21 wherein the BIST controller writes and reads the memory array at the processor operating frequency.

25. The processor of claim 21 wherein the first selector additionally selectively directs a fixed data pattern to the first comparator read data input, wherein the BIST controller receives a system reset, and wherein the BIST controller is further operative to control the first selector to direct the fixed data pattern to the first comparator following a reset.

26. The processor of claim 21 further comprising:
a second data comparator having read data and compare data inputs, and outputting an indication whether the read data match the compare data pattern;
a second selector selectively directing data from two or more second read ports to the second comparator read data input; and
wherein the BIST controller further controls the second read ports and the second selector, provides compare data to the second comparator compare data input, and receives the second comparator output, the BIST controller further operative to:
write one or more predetermined data pattern to the array via the write port;
simultaneously read the written data from the array via two or more first read ports and two or more second read ports; and
sequentially control the first and second selectors in parallel to direct data from each respective first and second read port to the respective comparator, provide corresponding compare data to the respective comparator, and verify the array by inspecting the first and second comparator outputs.
